(19) United States
(12) Patent Application Publication
(10) Pub. No.: US 2006/0141654 A1
(43) Pub. Date: Jun. 29, 2006

(54) Method for fabricating a CMOS image sensor

(76) Inventor: Bi O. Lim, Seoul (KR)

Correspondence Address: MCKENNA LONG & ALDRIDGE LLP, 1900 K STREET, NW, WASHINGTON, DC, 20006, US

(21) Appl. No.: 11/312,448

(22) Filed: Dec. 21, 2005

(30) Foreign Application Priority Data
Dec. 24, 2004 (KR) 10-2004-0112027

(51) Int. Cl. H01L 21/00

(52) U.S. Cl. 438/48

(57) ABSTRACT

A method for fabricating a CMOS image sensor in which an electron shower is performed for microlenses whose surfaces are charged to a positive potential, so as to neutralize the positive potential, thereby improving performance and yield of the image sensor.

### CROSS-REFERENCE TO RELATED APPLICATIONS

This application claims the benefit of the Korean Patent Application No. P2004-112027, filed on Dec. 24, 2004, which is hereby incorporated by reference as if fully set forth herein.

### BACKGROUND OF THE INVENTION

1. Field of the Invention

The present invention relates to a complementary metal-oxide semiconductor (CMOS) image sensor, and more particularly, to a CMOS image sensor and a method for fabricating the same, in which the performance of the CMOS image sensor is improved and, at the same time, its yield is improved.

2. Discussion of the Related Art

An image sensor is a semiconductor device that converts optical images to electrical signals. The image sensor is classified into a charge coupled device (CCD) and a CMOS image sensor.

The CCD has drawbacks in its fabrication process because of a complicated driving mode, high power consumption, and multistage photolithographic processes. Also, it is difficult for a control circuit, a signal processing circuit, and an analog-to-digital converter to be integrated in a CCD chip and still obtain a slim size product.

Recently, the CMOS image sensor has received much attention as an image sensor for the next generation to overcome the drawbacks of the CCD.

The CMOS image sensor employs a switching mode that sequentially detects outputs of unit pixels using MOS transistors by forming MOS transistors corresponding to the number of the unit pixels on a semiconductor substrate using CMOS technology that uses a control circuit and a signal processing circuit as peripheral circuits.

The CMOS image sensor has low power consumption because of the CMOS technology, and the fabrication process is simple because of a relatively small number of photolithographic process steps. Further, since the CMOS image sensor allows a control circuit, a signal processing circuit, and an analog-to-digital converter to be integrated in its chip, it has an advantage in that a slim sized product can be obtained.

Therefore, the CMOS image sensor is widely used for various application fields such as digital still camera and digital video camera.

A general CMOS image sensor will be described with reference to FIGS. 1 and 2. FIG. 1 is a circuit diagram illustrating a 3T type CMOS image sensor including three transistors, and FIG. 2 is a layout illustrating a unit pixel of the CMOS image sensor shown in FIG. 1.

A unit pixel of the 3T type CMOS image sensor, as shown in FIG. 1, includes a photodiode PD and three NMOS transistors T1, T2 and T3. A cathode of the photodiode PD is connected to a drain of the first nMOS transistor T1 and a gate of the second NMOS transistor T2.

Sources of the first and second NMOS transistors T1 and T2 are connected to a power terminal supplied with a reference voltage VR. A gate of the first NMOS transistor T1 is connected to a reset terminal supplied with a reset signal RST.

Further, a source of the third NMOS transistor T3 is connected to a drain of the second nMOS transistor T2, its source is connected to a reading circuit (not shown) through a signal line, and its gate is connected to a heat selection terminal supplied with a heat selection signal SLCT.

Therefore, the first NMOS transistor T1 is called a reset transistor Rx, the second nMOS transistor T2 is called a drive transistor Dx, and the third NMOS transistor T3 is called a selection transistor Sx.

In the unit pixel of the 3T type CMOS image sensor, as shown in FIG. 2, a photodiode 20 is formed in a wide portion of an active area 10, and gate electrodes 120, 130, and 140 of three transistors are formed to respectively overlap the other portions of the active area 10.

In this manner, the reset transistor Rx is formed by the gate electrode 120, the drive transistor Dx is formed by the gate electrode 130, and the selection transistor Sx is formed by the gate electrode 140.

Impurity ions are implanted into the active area 10 of each transistor except portions below the gate electrodes 120, 130 and 140, so that source and drain areas of each transistor are formed.

A power voltage Vdd is applied to the source and drain areas between the reset transistor Rx and the drive transistor Dx, and the source and drain areas at one side of the selection transistor Sx are connected to a reading circuit (not shown).

Although not shown, the gate electrodes 120, 130 and 140 are each connected to a respective signal line. Each signal line is provided with a pad at one end to be connected to an external driving circuit.

Process steps of forming the aforementioned pad in the CMOS image sensor and later process steps will be described with reference to FIG. 3A to FIG. 3E.

First, as shown in FIG. 3A, an insulating layer 101 (for example, oxide layer) such as a gate insulating layer or an interlayer insulating layer is formed on a semiconductor substrate 100. A metal pad 102 of each signal line is formed on the insulating layer 101.

The metal pad 102 may be formed of the same material as that of the gate electrodes 120, 130 and 140 on the same layer as the gate electrodes 120, 130 and 140. Alternatively, the metal pad 102 may be formed of a material different from that of the gate electrodes 120, 130 and 140 through a separate contact hole.

A passivation layer 103 is formed on an entire surface of the insulating layer 101 including the metal pad 102. The passivation layer 103 is formed of an oxide layer or a nitride layer.

As shown in FIG. 3B, a photoresist film 104 is coated on the passivation layer 103 and then patterned by exposing and developing processes to expose a portion of the passivation layer corresponding to the metal pad 102.

The passivation layer 103 is selectively etched using the patterned photoresist film 104 as a mask to form an open portion 105 in the metal pad 102.

Next, as shown in FIG. 3C, the photoresist film 104 is removed, and a first planarization layer 106 is deposited on an entire surface of the passivation layer 103. The first planarization layer 106 is removed by a photolithographic process using a mask to remain only in a portion other than the metal pad.

A blue color filter layer 107, a green color filter layer 108 and a red color filter layer 109 are sequentially formed on the first planarization layer corresponding to each photodiode area (not shown). Each color filter layer is formed in such a manner that a corresponding color resist is coated and the photolithographic process is performed using a separate mask.

As shown in FIG. 3D, a second planarization layer 111 is deposited on the entire surface of the semiconductor substrate including the respective color filter layers 107, 108 and 109. The second planarization layer 111 is then removed by the photolithographic process using a mask to remain only in a portion other than the metal pad.

As shown in FIG. 3E, microlenses 112 are formed on the second planarization layer 111 to correspond to the respective color filter layers 107, 108 and 109.

Each metal pad 102 of the CMOS image sensor fabricated as above undergoes a probe test to check contact resistance. As a result, if no problem is found, the metal pad is electrically connected with an external driving circuit.

The related art CMOS image sensor has several problems.

After the open portion is formed in the metal pad, the first planarization layer, the respective color filter layers, the second planarization layer, and the microlenses are formed. Since each process is performed while the metal pad is exposed, the metal pad is continuously exposed to a TMAH based alkali solution (at least three times when the color filter layers are formed). For this reason, a problem occurs in that the metal pad is corroded to cause a pit, thereby deteriorating reliability of the image sensor along with its yield.

To solve such a problem, the microlenses may be formed after a barrier is formed on the entire surface of the semiconductor substrate including the open portion of the metal pad. Since the barrier is removed while the microlenses are exposed, the microlenses exposed to plasma became positively charged. Microlenses with a positive potential trap photons when the image sensor is operated. For this reason, an optical signal does not reach a signal input portion. As a result, performance of the image sensor is deteriorated and its yield is reduced.

### SUMMARY OF THE INVENTION

Accordingly, the present invention is directed to a method for fabricating a CMOS image sensor that substantially obviates one or more problems due to limitations and disadvantages of the related art.

An advantage of the present invention is that it provides a method for fabricating a CMOS image sensor, in which electron shower is performed for microlenses whose surfaces are charged to have a positive potential, so as to neutralize the conducted potential, thereby improving performance and yield of the image sensor.

Additional advantages and features of the invention will be set forth in part in the description which follows and in part will become apparent to those having ordinary skill in the art upon examination of the following or may be learned from practice of the invention. These and other advantages of the invention may be realized and attained by the structure particularly pointed out in the written description and claims hereof as well as the appended drawings.

To achieve these and other advantages and in accordance with the purpose of the invention, as embodied and broadly described herein, a method for fabricating a CMOS image sensor includes forming a metal pad in a pad area over a semiconductor substrate divided into an active area and the pad area, forming a passivation layer on an entire surface of the semiconductor substrate including the metal pad, selectively removing the passivation layer to expose the metal pad, thereby forming a metal pad open portion, forming a barrier layer on the entire surface of the semiconductor substrate including the metal pad open portion, forming R, G and B color filter layers over the barrier layer of the active area, forming microlenses over the color filter layers, removing the barrier layer of the pad area, and performing electron shower to neutralize positive potential trapped in the microlenses.

The barrier layer is removed by reactive ion etching (RIE). When the barrier layer is removed by the RIE, curing is performed using N₂ gas to remove a corrosive material that may remain on a surface of the metal pad.

The method may further include forming an insulating layer on the semiconductor substrate prior to forming the metal pad the semiconductor substrate.

The method may further include forming first planarization layers on the barrier layer of the active area before forming color filter layers over the barrier layer of the active area and forming second planarization layers on the color filter layers before forming the microlenses over the color filter layers.

The method may further include forming first planarization layers before forming color filter layers and forming second planarization layers before forming the micro lenses.

The method may further include respectively forming first and second planarization layers between the barrier layer and the color filter layers and between the color filter layers and the microlenses.

Preferably, the barrier layer is formed of a PE oxide film, PE TEOS, or PE nitride film, and the barrier layer is formed at a thickness of 200 Å to 600 Å. The metal pad is formed of aluminum.

Furthermore, the electron shower is performed using electron beam. In another modified embodiment, the electron shower is performed using a filament through heat electrons generated by a current flowing in the filament. At this time, the semiconductor substrate is applied with a positive voltage and the filament is applied with a negative voltage, so that the heat electrons generated from the filament are induced to the semiconductor substrate.

Furthermore, the electron shower is performed using a magnet or a potential layer to increase electron mobility. The electron shower is performed under high vacuum to increase a range of the electrons.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention.

In the drawings:

FIG. 1 is an equivalent circuit diagram illustrating a typical 3T type CMOS image sensor;

FIG. 2 is a layout illustrating a unit pixel of a general CMOS image sensor shown in FIG. 1;

FIG. 3A to FIG. 3E are sectional views illustrating a method for fabricating a related art CMOS image sensor;

FIG. 4A to FIG. 4G are sectional views illustrating a method for fabricating a CMOS image sensor according to the an embodiment of the present invention; and

FIG. 5 illustrates how the electron shower may be performed using a filament in accordance with an embodiment of the present invention.

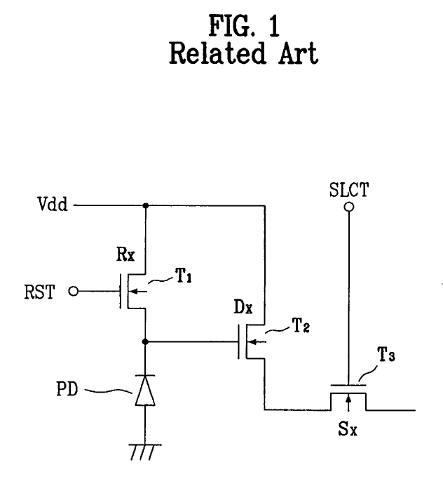

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or like parts.

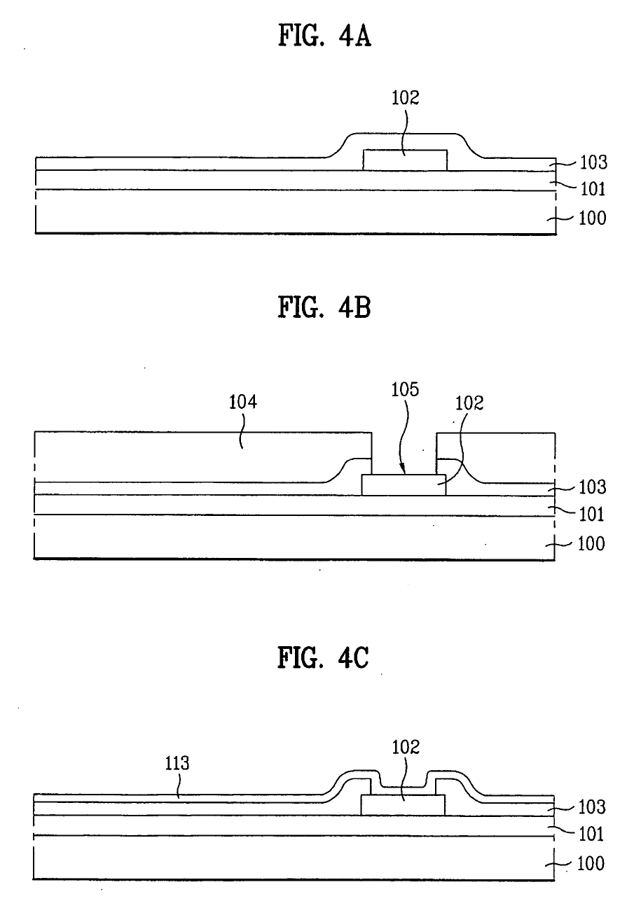

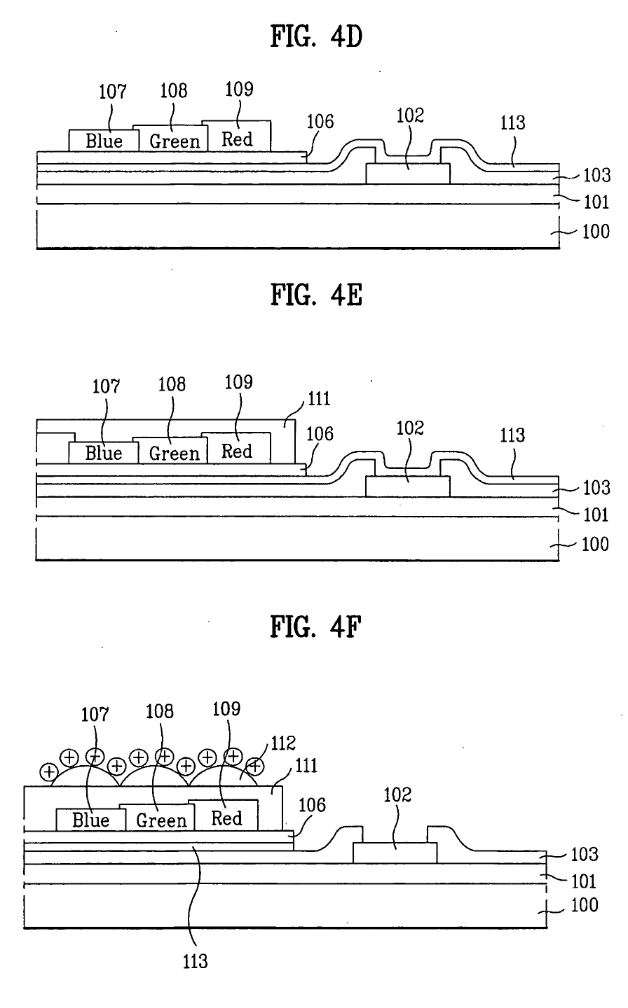

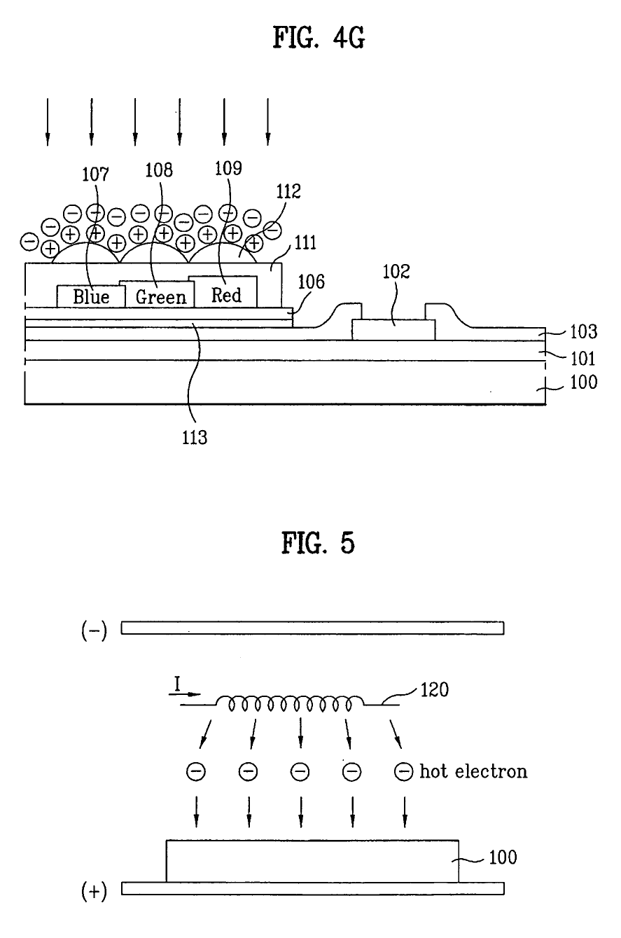

FIG. 4A to FIG. 4G are sectional views illustrating a method for fabricating a CMOS image sensor according to the an exemplary embodiment of the present invention.

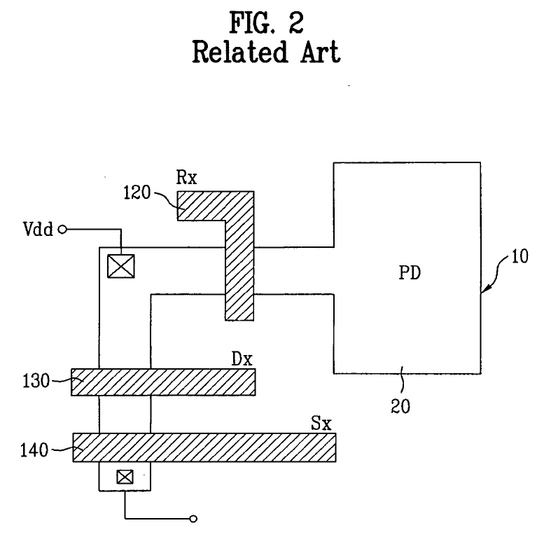

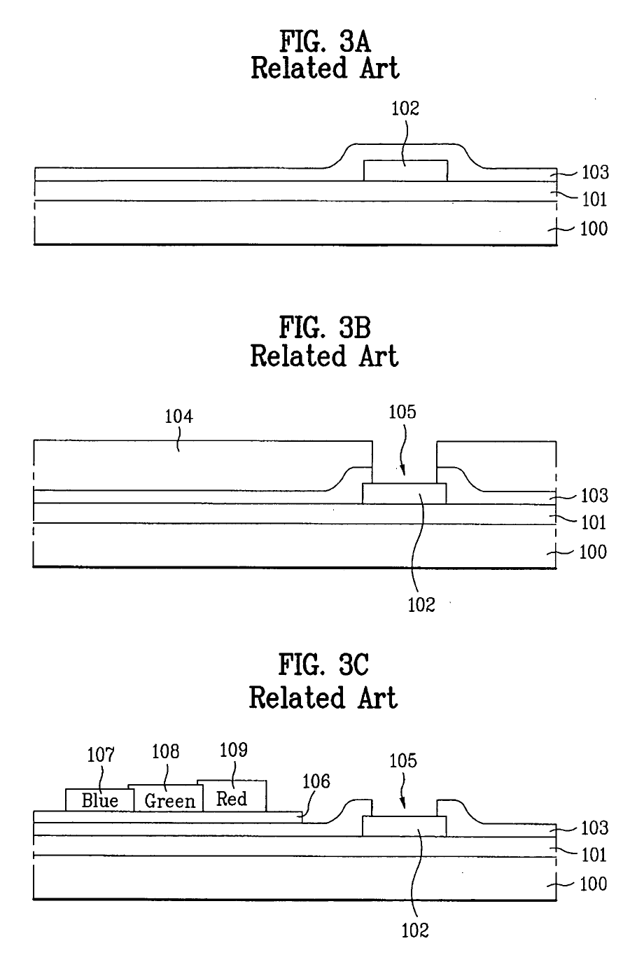

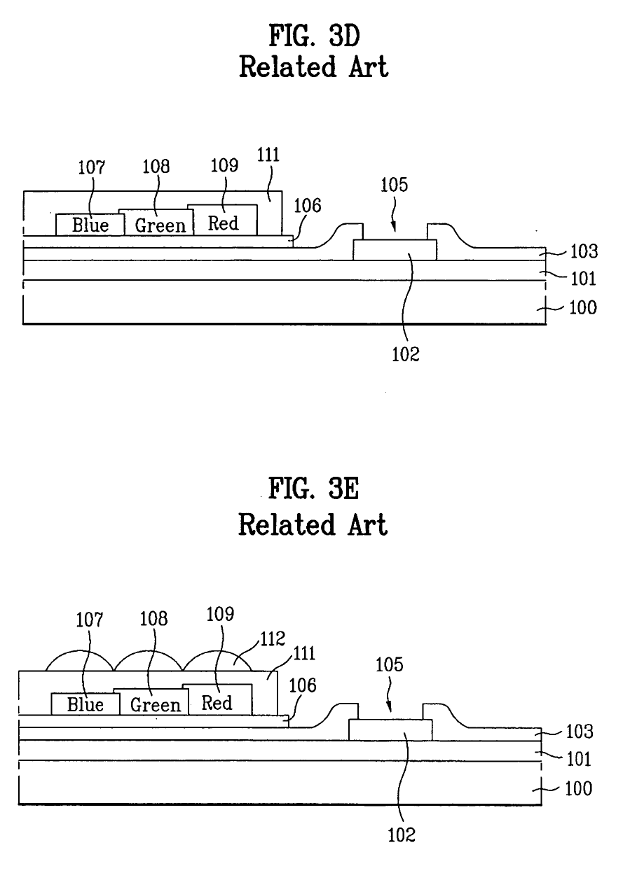

As shown in FIG. 4A, an insulating layer 101 such as a gate insulating layer or an interlayer insulating layer is formed on a semiconductor substrate 100. A metal pad 102 of each signal line is formed on the insulating layer 101. The metal pad 102 may be formed of the same material as that of respective gate electrodes 120, 130 and 140 shown in FIG. 2 on the same layer as the gate electrodes 120, 130 and 140. Alternatively, the metal pad 102 may be formed of a material different from that of the gate electrodes 120, 130 and 140 through a separate contact hole. Optionally, the metal pad 102 may be formed of aluminum (Al).

Next, a passivation layer 103 is formed on an entire surface of the insulating layer 101 including the metal pad 102. The passivation layer 103 may be formed of an oxide layer or a nitride layer.

As shown in FIG. 4B, a photoresist film 104 is coated on the passivation layer 103 and then patterned by exposing and developing processes using photolithography to partially expose the passivation layer corresponding to the metal pad 102. The passivation layer 103 is selectively etched using the patterned photoresist film 104 as a mask to form a metal pad open portion 105 in the metal pad 102. Then, the photoresist film 104 is removed.

As shown in FIG. 4C, a barrier layer 113 is formed on an entire surface of the semiconductor substrate including the open portion 105. The barrier layer 103 may be formed of a plasma enhancement (PE) oxide film, such as PE TEOS or PE nitride, at a thickness of approximately 200 Å to 600 Å.

As shown in FIG. 4D, a first planarization layer 106 is deposited on an entire surface of the barrier layer 113 and then removed by a photolithographic process using a mask to remain only in a portion other than the metal pad.

A blue color filter layer 107, a green color filter layer 108 and a red color filter layer 109 are sequentially formed on the first planarization layer 106 corresponding to each photodiode area (not shown). Each color filter layer is formed in such a manner that a corresponding photoresist material is coated and the photolithographic process is performed using a separate mask.

As shown in FIG. 4E, a second planarization layer 111 is deposited on the entire surface of the semiconductor substrate including the respective color filter layers 107, 108 and 109. The second planarization layer 111 is then removed by the photolithographic process using a mask to remain only in a portion other than the metal pad.

As shown in FIG. 4F, a dielectric material is deposited on the second planarization layer 111 and then selectively removed by the photolithographic process. Afterwards, microlenses 112 are formed on the second planarization layer 111 to correspond to the respective color filter layers 107, 108 and 109.

The barrier layer 113 on the metal pad 102 is then removed by reactive ion etching (RIE) to expose the open portion 105 of the metal pad. Since a material, such as fluorine ions, which can corrode the metal pad 102, may exist on the surface of the metal pad 102, curing is performed using N₂ gas to remove the fluorine ions remaining on the surface of the metal pad 102.

As described above, since the barrier layer 113 is removed while the microlenses 112 are exposed, the microlenses 112 are charged to a positive potential.

Therefore, as shown in FIG. 4G, negative potential is applied to the microlenses 112 through an electron shower, thereby neutralizing the positive potential of the micro lenses.

In an exemplary embodiment of the present invention, the electron shower may be performed using an electron beam or a filament.

In the case where the electron shower is performed using a filament, as shown in FIG. 5, a negative voltage is applied to the filament 120 while a positive voltage is applied to the semiconductor substrate 100. Heat electrons generated by a current flowing in the filament 120 are induced to the semiconductor substrate 100.

To improve efficiency of the electrons, a magnet or a potential layer may be used to increase electron mobility. To increase a range of the electrons, the electron shower may be performed under high vacuum.

As described above, the CMOS image sensor and the method for fabricating the same according to the present invention may have the following advantages.

First, after the open portion of the metal pad is formed, since the barrier layer is formed to protect the metal pad from a developing solution or an etching solution used in a later process, it is possible to prevent the metal pad from being corroded, thereby reducing contact resistance of the metal pad.

Second, when the barrier layer is removed, the negative potential is applied to the microlenses through the electron shower so as to neutralize the positive potential trapped in the surfaces of the microlenses. Because photon trapping is avoided, it is possible to improve performance and yield of the image sensor.

Finally, since the electron shower may be performed, the process can be performed without damage of the image sensor.

It will be apparent to those skilled in the art that various modifications and variations can be made in the present invention without departing from the spirit or scope of the inventions. Thus, it is intended that the present invention cover the modifications and variations of this invention provided they come within the scope of the appended claims and their equivalents.

What is claimed is:

1. A method for fabricating a CMOS image sensor comprising:
forming a metal pad in a pad area over a semiconductor substrate divided into an active area and the pad area;
forming a passivation layer on an entire surface of the semiconductor substrate including the metal pad;
selectively removing the passivation layer to expose the metal pad, thereby forming a metal pad open portion;
forming a barrier layer on the entire surface of the semiconductor substrate including the metal pad open portion;
forming R, G and B color filter layers over the barrier layer of the active area;
forming microlenses over the color filter layers;
removing the barrier layer of the pad area; and
performing electron shower to neutralize positive potential trapped in the microlenses.

2. The method as claimed in claim 1, wherein the barrier layer is removed by reaction ion etching (RIE).

3. The method as claimed in claim 2, further comprising curing using N₂ gas to remove a corrosive material that may remain on a surface of the metal pad when the barrier layer is removed by the RIE.

4. The method as claimed in claim 1, further comprising forming an insulating layer on the semiconductor substrate prior to forming the metal pad the semiconductor substrate.

5. The method as claimed in claim 1, further comprising forming first planarization layers on the barrier layer of the active area before forming color filter layers over the barrier layer of the active area and forming second planarization layers on the color filter layers before forming the microlenses over the color filter layers.

6. The method as claimed in claim 1, wherein the barrier layer is formed of a PE oxide film, PE TEOS, or PE nitride film.

7. The method as claimed in claim 1, wherein the barrier layer is formed at a thickness of about 200 Å to 600 Å.

8. The method as claimed in claim 1, wherein the metal pad is formed of aluminum.

9. The method as claimed in claim 1, wherein the electron shower is performed using electron beam.

10. The method as claimed in claim 1, wherein the electron shower is performed using a filament through heat electrons generated by a current flowing in the filament.

11. The method as claimed in claim 10, wherein a positive voltage is applied to the semiconductor substrate and a negative voltage is applied to the filament, so that the heat electrons generated from the filament are induced to the semiconductor substrate.

12. The method as claimed in claim 1, wherein the electron shower is performed using a magnet or a potential layer to increase electron mobility.

13. The method as claimed in claim 1, wherein the electron shower is performed under high vacuum to increase a range of the electrons.

14. A method of neutralizing a positive potential stored in a microlens of an image sensor device comprising:
performing an electron shower on the microlens.

15. The method as claimed in claim 14, wherein the electron shower is performed using a filament through heat electrons generated by a current flowing in the filament.

16. The method as claimed in claim 15, wherein a positive voltage is applied to the device and a negative voltage is applied to the filament, so that the heat electrons generated from the filament are induced to the device.

17. The method as claimed in claim 14, wherein the electron shower is performed using a magnet or a potential layer to increase electron mobility.

18. The method as claimed in claim 14, wherein the electron shower is performed under high vacuum to increase a range of the electrons.
